(19) United States
(12) Patent Application Publication
(10) Pub. No.: US 2024/0354459 A1
(43) Pub. Date: Oct. 24, 2024

(54) SPATIAL STRUCTURE ANALYSIS AND REGENERATION DECISION-MAKING METHOD FOR RESIDENTIAL HISTORIC AREA

(71) Applicant: SOUTHEAST UNIVERSITY, Nanjing (CN)

(72) Inventors: Yacheng SONG, Nanjing (CN); Zhiyu PANG, Nanjing (CN); Dongqing HAN, Nanjing (CN); Yinan DONG, Nanjing (CN); Zhehao SONG, Nanjing (CN)

(73) Assignee: SOUTHEAST UNIVERSITY, Nanjing (CN)

(21) Appl. No.: 18/702,812

(22) PCT Filed: Nov. 20, 2023
(86) PCT No.: PCT/CN2023/132532

§ 371 Date: Apr. 19, 2024

(30) Foreign Application Priority Data
Apr. 19, 2023 (CN) 202310422164.2

(51) Int. Cl. G06F 30/13

(52) U.S. Cl. CPC G06F 30/13

(57) ABSTRACT

The method includes the following steps: first establishing urban street and urban plot elements, delineating publicly used parts of public and private property areas as streets, and delineating boundaries of privately owned land as plots; after defining urban streets and urban plots, obtaining accessibility levels of the street elements through depth, connectivity, and low connection rate, where the accessibility level of an urban plot includes an external value and an internal value, the external value is obtained through the levels of urban streets connected to the plot, and the internal value is obtained through the delineation of interlocking structure, basic structure, cul-de-sac structure, and embedding structure types of the urban plot and the urban streets; and based on calculation results of the accessibility levels of the urban streets and urban plots, making judgments from four aspects: upper level planning, commercial system, community system, and historic resources.

### CROSS REFERENCE TO THE RELATED APPLICATIONS

This application is the national phase entry of International Application No. PCT/CN2023/132532, filed on Nov. 20, 2023, which is based upon and claims priority to Chinese Patent Application No. 202310422164.2, filed on Apr. 19, 2023, the entire contents of which are incorporated herein by reference.

### TECHNICAL FIELD

The present invention belongs to the field of urban regeneration technology, and specifically relates to a spatial structure analysis and regeneration decision-making method for a residential historic area.

### BACKGROUND

Residential historic areas face particularly complex urban regeneration issues. They not only preserve street and alley textures, spatial forms, traditional styles and material relics of specific historic stages, but also inherit various distinctive social structures, living behaviors and folk customs. After multiple historic periods of morphological accumulation, built environments of the residential historic areas generally present complex spatial structures, and cognitions on internal logics of streets and plot spaces are greatly difficult. There are a large number of “T” junctions and cul-de-sac roads, and even originally private internal roads of plots are integrated into an urban public environment over a long period of use to function as public streets, which increase spatial levels of streets. There are also complex correlations between adjacent property right plots, and entrances of some property right plots are not directly connected to urban streets, but cross other property right plots.

In previous research on street networks, British scholar Hillier B proposed a spatial syntax that describes topological connections between street networks through a graph theory method, and correspondingly proposed calculation methods such as “integration” and “choice”. Marshall S proposed a “route structure” method to research configuration characteristics of streets, proposed to describe the configuration characteristics of streets through continuity, connectivity, and depth indicators, and established a series of measuring methods. Ge Xin and Han Dongqing made local improvements on the route structure method to determine types of internal streets through three indicators: depth, connectivity, and low connection rate. Song Yacheng proposed interlocking degree, co-inflection degree, and embedding degree indicators to analyze the complexity of plot structures. However, none of the above methods have combined a street network structure with a plot structure for comprehensive analysis, and have not provided comprehensive guidance for urban regeneration practice projects such as residential historic areas in China.

### SUMMARY

In response to the shortcomings of existing technologies, the present invention aims to provide a spatial structure analysis and regeneration decision-making method for a residential historic area to solve the problems raised in the background.

The objective of the present invention can be achieved through the following technical solution:

A spatial structure analysis and regeneration decision-making method for a residential historic area includes the following steps:
step 1: first establishing urban street and urban plot elements, delineating publicly used parts of public and private property areas as streets, and delineating boundaries of privately owned land as plots;
step 2: after defining urban streets and urban plots, obtaining accessibility levels of the street elements through depth, connectivity, and low connection rate, where the accessibility level of an urban plot includes an external value and an internal value, the external value is obtained through the levels of urban streets connected to the plot, the internal value is obtained through the delineation of interlocking structure, basic structure, cul-de-sac structure, and embedding structure types of the urban plot and the urban streets, and the accessibility levels decrease sequentially; and
step 3: based on calculation results of the accessibility levels of the urban streets and urban plots, making judgments from four aspects: upper level planning, commercial system, community system, and historic resources.

Preferably, areas that have public property rights but have been privatized for use need to be removed, paths that have private property rights but are actually used by the public need to be added, and cul-de-sac roads are not involved in street network calculation.

Preferably, the depth definition process in step 2 includes: defining an urban main road as a “base” depth, with a depth of 0, where the depth value of a street directly connected to the “base” is 1, the depth value of a street connected to the depth 1 street is 2, and so on.

Preferably, the connectivity in step 2 is a quantity of streets connected to a street.

Preferably, the low connection rate in step 2 is a proportion of a street connected to low depth streets.

Preferably, the urban main road in step 2 does not participate in clustering, but is directly set as a type having the highest accessibility level.

Preferably, the external value in step 2 depends on the accessibility levels of streets connected to a specific plot, and when a plot is connected to two or more streets, the external value depends on the accessibility level of the street having the higher accessibility level.

Preferably, in step 2, the interlocking structure is that the plot is connected to a plurality of streets, the basic structure is that the plot is connected to only one street, the cul-de-sac structure is of a plot entered through a cul-de-sac road, and the embedding structure is that the plot is not directly connected to any street, but can be entered from a street after passing through other plots.

Beneficial effects of the present invention are as follows:

1. Aiming at a complex built environment of a residential historic area, the method of the present invention comprehensively utilizes a spatial configuration method for a street network and plot structures to quantitatively describe level relationships between different form elements and analyze overall spatial structure characteristics, so as to provide a method for regeneration and renovation.

### BRIEF DESCRIPTION OF THE DRAWINGS

In order to describe the technical solutions in the embodiments of the present invention or in the prior art more clearly, the following briefly introduces the accompanying drawings required in the description of the embodiments or the prior art. Apparently, those of ordinary skill in the art can derive other drawings from these drawings without any creative effort.

FIG. 1 is a flowchart of a method in an embodiment of the present invention;

FIG. 2 is a diagram showing three indicators of street elements in an embodiment of the present invention;

FIG. 3 is a diagram showing four basic types of relationships between plots and streets in an embodiment of the present invention;

FIG. 4 is an image of Hehuatang and Diaoyutai blocks in an embodiment of the present invention;

FIG. 5 is a diagram showing street network accessibility levels of Hehuatang and Diaoyutai blocks in an embodiment of the present invention; and

FIG. 6 is a diagram showing plot accessibility levels of Hehuatang and Diaoyutai blocks in an embodiment of the present invention.

### DETAILED DESCRIPTION OF THE EMBODIMENTS

The technical solutions in the embodiments of the present invention will be clearly and completely described below in conjunction with the accompanying drawings in the embodiments of the present invention. Apparently, the described embodiments are only some, not all of the embodiments of the present invention. All other embodiments obtained by those of ordinary skill in the art based on the embodiments of the present invention without any creative efforts fall within the scope of protection of the present invention.

The method combines a street network structure with a plot structure for global analysis, and provides decision-making suggestions for urban regeneration practice of a residential historic area. For street elements, a calculation method is put forward for three basic indicators: depth, connectivity, and low connection rate, and accessibility levels of the street elements are obtained by cluster analysis. For a plot element, an external value is first obtained through the level of a connected street, an internal value is obtained through the delineation of four structure types: interlocking structure, basic structure, cul-de-sac structure, and embedding structure of the plot and the street, and an accessibility level of the plot is obtained by combining the two. Finally, based on the calculation results of the street and the plot, judgments are made from four aspects: upper level planning, commercial system, community system, and historic resources, and optimization suggestions are provided.

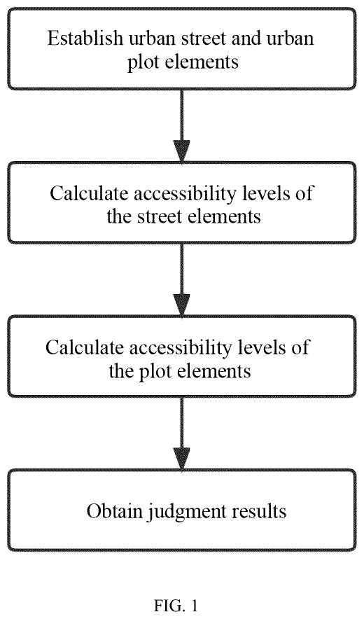

With reference to FIG. 1, this embodiment provides a spatial structure analysis and regeneration decision-making method for a residential historic area, including the following steps:

Step 1: First, urban street and urban plot elements are established, public property areas are delineated as streets, and boundaries of privately owned land are delineated as plots;

Step 2: After urban streets and urban plots are defined, accessibility levels of the street elements are obtained through depth, connectivity, and low connection rate, where the accessibility level of an urban plot includes an external value and an internal value, the external value is obtained through the levels of urban streets connected to the plot, and the internal value is obtained through the delineation of interlocking structure, basic structure, cul-de-sac structure, and embedding structure types of the urban plot and the urban streets;

Step 3: Based on calculation results of the accessibility levels of the urban streets and urban plots, judgments are made on four aspects: upper level planning, commercial system, community system, and historic resources, and optimization suggestions are provided.

For determining street and plot elements in step 1, property right plot information is first obtained from the government department, then public property areas are delineated as streets, and boundaries of privately owned land are delineated as plots. Based on field research, the actual usage is investigated to ensure that paths ultimately involved in calculation are relatively public streets. Areas that have public property rights but have been privatized for use are removed, and then paths that have private property rights but are actually used by the public are added. Cul-de-sac roads are not involved in street network calculation.

In step 2, an urban main road adjacent to the residential historic area is first defined as a “base” depth, that is, its depth is 0. The depth value of a street directly connected to the “base” is 1, the depth value of a street connected to the depth 1 street is 2, and so on.

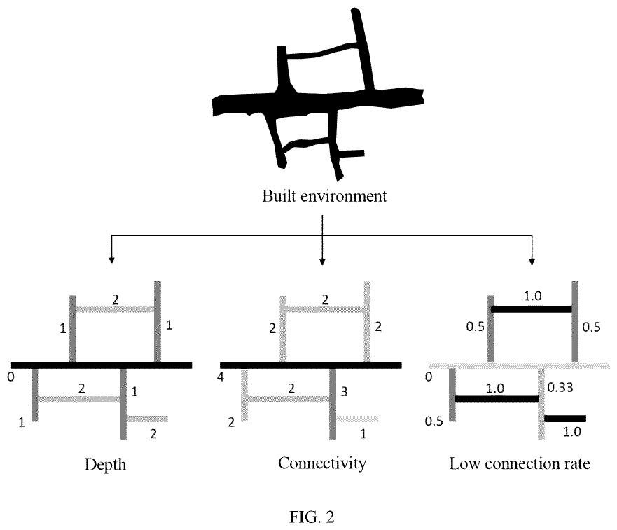

The quantity of other streets connected to a street is connectivity. If a street is connected to 3 streets, the connectivity value of the street is 3. Low connection rate represents a proportion of a street connected to low depth streets. If the connectivity of a street with a depth of 2 is 5 and the quantity of streets with a depth of 0 or 1 connected to the street is 2, its low connection rate is 0.4. The three indicators are comprehensively classified using K-means clustering in SPSS software to obtain the accessibility levels of street elements, as shown in FIG. 2. It should be noted that the urban main road does not participate in clustering, but is directly set as a type having the highest accessibility level.

The accessibility level of a plot is an integrated result of external and internal values. The external value depends on the accessibility levels of streets connected to a specific plot: if a plot is connected to only one street, the external level value of the plot is 1, medium level streets correspond to level 2, and low level streets correspond to level 3; if a plot is connected to two or more streets, the external level value depends on the higher one.

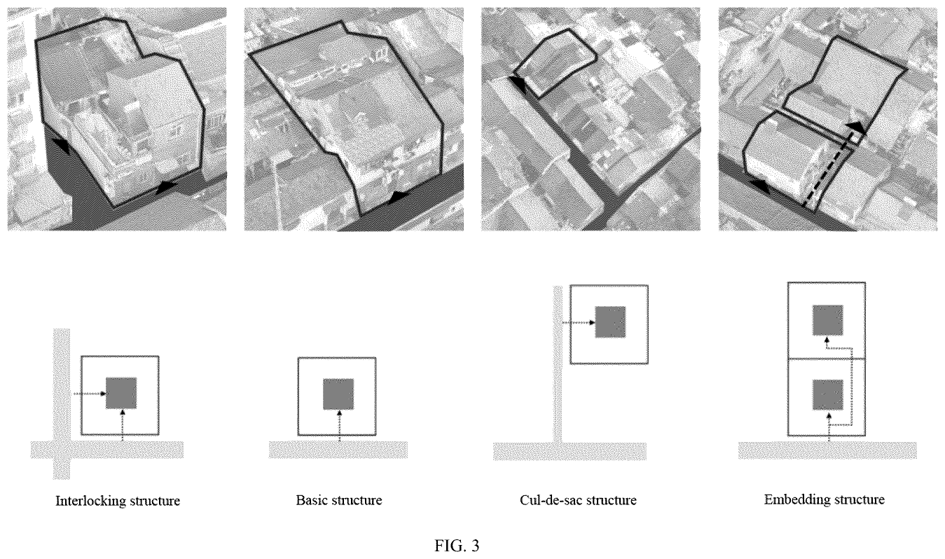

The internal level value of the plot is determined according to the relationship between the plot and the streets, including four types, with accessibility levels in descending order: the first type is an interlocking structure, where the plot is connected to a plurality of streets (not cul-de-sac roads); the second type is a basic structure, where the plot is connected to only one street (not a cul-de-sac road); the third type is a plot entered through a cul-de-sac road; and the fourth type is a embedding structure, where the plot is not directly connected to any street, but can be entered from a street after passing through other plots, as shown in FIG. 3.

A two-dimensional coordinate map is drawn by integrating the accessibility levels of the streets and plots, where the horizontal axis represents external levels and the vertical axis represents internal levels. The plot with highest internal and external levels is defined as a highest accessibility level, the plot with two lowest values is defined as a lowest level, and the plots having the same sum of two values are considered as the same level, showing a trend of decreasing levels from bottom left to top right. Based on the above rules, a comprehensive accessibility level map of all plots can be obtained. The comprehensive accessibility levels of the plots are divided into six levels.

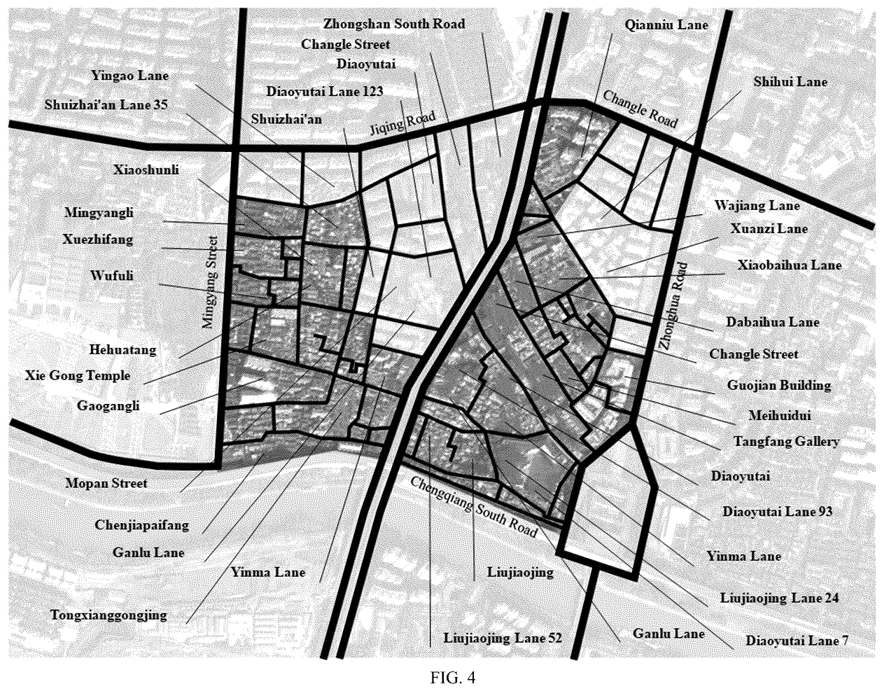

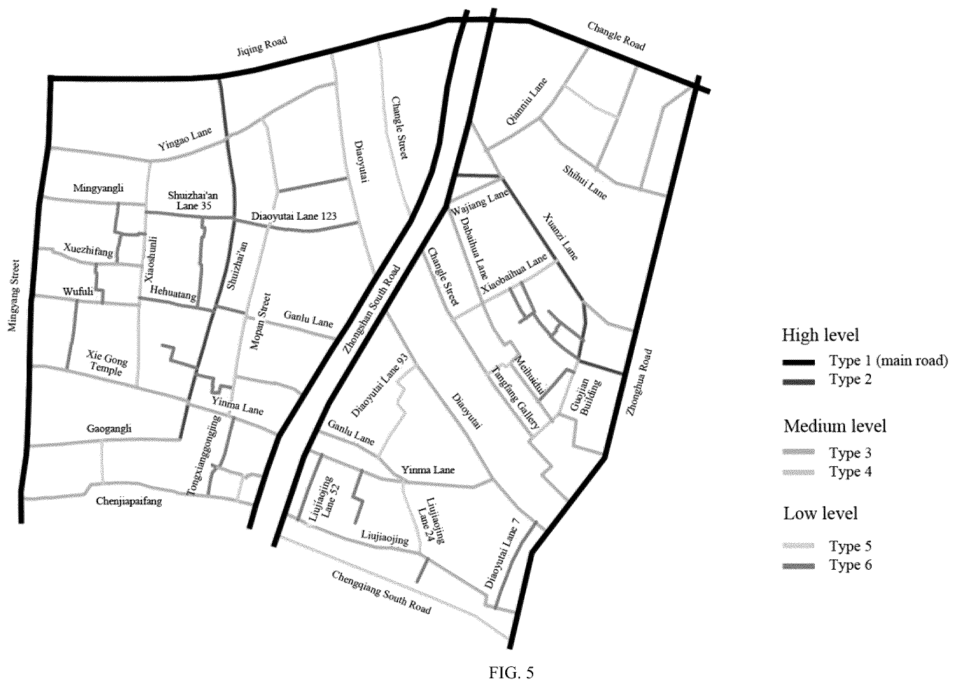

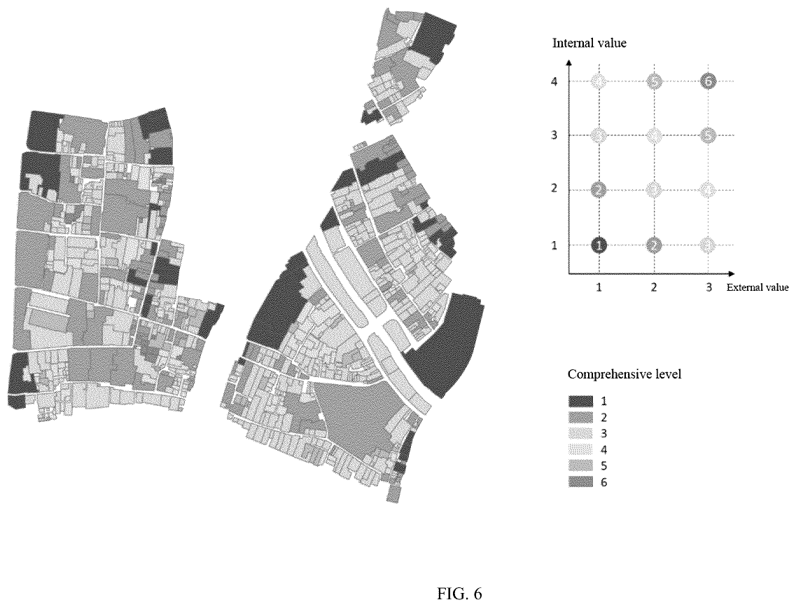

Judgments are made based on the contents of the above steps and actual project requirements from four perspectives: upper level planning, commercial system, community system, and historic resources, and suggestions are provided. Hehuatang and Diaoyutai blocks are used for simulation. An image of the Hehuatang and Diaoyutai blocks is shown in FIG. 4. Street network accessibility levels of the Hehuatang and Diaoyutai blocks and plot accessibility levels of the Hehuatang and Diaoyutai blocks are then calculated, as shown in FIG. 5 and FIG. 6. The street network accessibility levels are divided into high, medium, and low levels. High level streets and plots are suitable for developing urban level commercial systems; medium level streets and plots are suitable for laying out community level public service facilities; low level streets and plots are not suitable for laying out commercial and public service facilities; the low level plots may cause inconvenience for usage, and should be removed as much as possible during regeneration; historic streets and plots require more resources for revitalization and utilization, and their accessibility levels should not be too low.

Finally obtained judgments on current situations and optimization suggestions are shown in Table 1.

TABLE 1

| Dimension | Judgment | Suggestion |
|---|---|---|
| Upper level | For urban vitality paths along the | In view of low depth values of |
| planning | Qinhuai River and city wall proposed | Diaoyutai Road, Changle Street, |
| | by the upper level planning, the | Chenjiapaifang and Liujiaojing, their |
| | analysis on street accessibility shows | accessibility is restricted by their low |
| | that the accessibilities of the two | connection rate, their connectivity is |
| | paths within the design scope do not | suggested to increase in planning. If |
| | meet corresponding level | the accessibility is unconditionally |
| | requirements. The levels of Diaoyutai | increased, alternative conditional |
| | Road and Changle Street are 3, which | similar streets can be considered. |
| | is not low within the design scope, | |
| | but they have not yet met the | |
| | requirements for undertaking urban | |
| | level functions when viewed in a | |
| | larger area. Chenjiapaifang and | |
| | Liujiaojing along the city wall belong | |
| | to low level streets, and cannot meet | |
| | the requirements | |
| Commercial | In addition to main urban roads, two | In addition to developing the two |
| system | high level streets Shuizhai'an and | high level streets Shuizhai'an and |
| | Xuanzi Lane are found within the | Xuanzi Lane into urban commercial |
| | block, and they are also currently | streets, the Xie Gong Temple and |
| | most dynamic streets, so they have | Yinma Lane streets in the east-west |
| | the most potential to develop into | direction can be strengthened for |
| | streets for undertaking urban level | accessibility, and upgraded to type 2 |
| | functions. Besides, commercial | high level streets by connecting paths |
| | streets within the planning scope are | and increasing connection values. |
| | mainly laid out in parallel in the | |
| | north-south direction, with a lack of | |
| | connection in the east-west direction. | |
| Community | When urban commercial activities are | In the current situation, Xiaoshunli, |
| system | introduced, the layout of community | Mopan Street, and Xiaobaihua Lane |
| | service facilities should be different | have the conditions to develop into |
| | and consider both mobility and | community service streets. In |
| | tranquility. So, type 3 blocks with | addition, the southern part of the |
| | some depth and high connectivity are | Diaoyutai block lacks type 3 streets, |
| | more suitable, | so Diaoyutai Lane 93 and Liujiaojing |
| | | Lane 24 have the conditions to |
| | | develop into service streets in terms |
| | | of length. |
| | Plot types 5 and 6 belong to plots | The accessibilities of entry streets can |
| | with low accessibility. Large areas of | be increased as much as possible by |
| | low accessibility land will affect the | clearing cul-de-sac roads, or more |
| | convenience of living and also cause | street entry options can be provided |
| | inconvenience to urban management. | for plots by combination and |
| | | recombination of the plots, so as to |
| | | achieve the purpose of reducing the |
| | | proportions of plot types 5 and 6. |
| Historic | Current historic preservation streets | Vibrant spaces can be created around |
| resources | have high accessibility, and their | important historic preservation |
| | basic layout is well maintained. | streets to revitalize and utilize |
| | | historic resources. |
| | Some historic preservation units have | The accessibility of historic |
| | low accessibility, which is not | preservation units can be properly |
| | conducive to display, such as | increased to maximize the integration |
| | Tongxianggongjing No. 11 residential | of historic and cultural resources into |
| | buildings, Diaoyutai No. 13, | the urban public activity system. |
| | Diaoyutai No. 17, and Yinma Lane | |
| | No. 38. | |

The above embodiments are only used for illustrating, but not limiting, the technical solutions of the present invention. Although the present invention is described in detail with reference to the above embodiments, those of ordinary skill in the art should understand that specific implementations of the present invention can still be modified or equivalently replaced, and any modification or equivalent replacement without deviating from the spirit and scope of the present invention should fall within the scope of protection of the claims of the present invention.

1. A spatial structure analysis and regeneration decision-making method for a residential historic area, comprising the following steps:
step 1: first establishing urban street and urban plot elements, delineating publicly used parts of public and private property areas as streets, and delineating boundaries of privately owned land as plots;
step 2: after defining urban streets and urban plots, obtaining accessibility levels of the street elements through a depth, a connectivity, and a low connection rate, wherein the accessibility level of an urban plot comprises an external value and an internal value, the external value is obtained through levels of the urban streets connected to the urban plot, the internal value is obtained through a delineation types of of an interlocking structure, a basic structure, a cul-de-sac structure, and an embedding structure of the urban plot and the urban streets, and the accessibility levels decrease sequentially; and
step 3: based on calculation results of the accessibility levels of the urban streets and urban plots, making judgments from four aspects: upper level planning, a commercial system, a community system, and historic resources.

2. The spatial structure analysis and regeneration decision-making method for a residential historic area according to claim 1, wherein in step 1, areas that have public property rights but have been privatized for use need to be removed, paths that have private property rights but are actually used by a public need to be added, and cul-de-sac roads are not involved in a street network calculation.

3. The spatial structure analysis and regeneration decision-making method for a residential historic area according to claim 1, wherein a depth definition process in step 2 comprises: defining an urban main road as a “base” with a depth value of 0, wherein a depth value of a street directly connected to the “base” is 1, a depth value of a street connected to the street with the depth value of 1 is 2, and so on.

4. The spatial structure analysis and regeneration decision-making method for a residential historic area according to claim 1, wherein the connectivity in step 2 is a quantity of streets connected to a street.

5. The spatial structure analysis and regeneration decision-making method for a residential historic area according to claim 1, wherein the low connection rate in step 2 is a proportion of a street connected to low depth streets.

6. The spatial structure analysis and regeneration decision-making method for a residential historic area according to claim 1, wherein the urban main road in step 2 does not participate in clustering, but is directly set as a type having a highest accessibility level.

7. The spatial structure analysis and regeneration decision-making method for a residential historic area according to claim 1, wherein the external value in step 2 depends on the accessibility levels of streets connected to a specific plot, and when a plot is connected to two or more streets, the external value depends on the accessibility level of the street having a higher accessibility level.

8. The spatial structure analysis and regeneration decision-making method for a residential historic area according to claim 1, wherein in step 2, the interlocking structure is that the plot is connected to a plurality of streets, the basic structure is that the plot is connected to only one street, the cul-de-sac structure is of the plot entered through a cul-de-sac road, and the embedding structure is that the plot is not directly connected to any street, but can be entered from a street after passing through other plots.
